(19) United States
(12) Patent Application Publication
(10) Pub. No.: US 2014/0030891 A1
(43) Pub. Date: Jan. 30, 2014

(54) METHOD OF MANUFACTURING SEMICONDUCTOR DEVICE AND APPARATUS FOR MANUFACTURING SEMICONDUCTOR DEVICE

(71) Applicant: KABUSHIKI KAISHA TOSHIBA, Tokyo (JP)

(72) Inventors: Susumu YAMAMOTO, Oita (JP); Michihiko KAWAMURA, Oita (JP); Gaku MINAMIHABA, Kanagawa (JP); Yasuhiro NAGASAWA, Oita (JP)

(73) Assignee: KABUSHIKI KAISHA TOSHIBA, Tokyo (JP)

(21) Appl. No.: 13/797,624

(22) Filed: Mar. 12, 2013

(30) Foreign Application Priority Data
Jul. 24, 2012 (JP) 2012-163852

(51) Int. Cl. H01L 21/302; H01L 21/67

(52) U.S. Cl. CPC H01L 21/302; H01L 21/67011
USPC 438/690; 156/345.12

(57) ABSTRACT

A method of manufacturing a semiconductor device according to an embodiment includes a process of forming a metal film on the surface of the insulation film with which a concave portion is filled and a first polishing process of polishing the surface of the metal film while supplying an oxidation agent containing no abrasive grains. The method of manufacturing the semiconductor device further includes a second polishing process of polishing the surface of the metal film while supplying a polishing agent excluding the oxidation agent to the surface of the metal film oxidized by the oxidation agent, after the first polishing process.

### CROSS-REFERENCE TO RELATED APPLICATIONS

This application is based upon and claims the benefit of priority from Japanese Patent Application No. 2012-163852, filed on Jul. 24, 2012; the entire contents of which are incorporated herein by reference.

### FIELD

Embodiments described herein relate generally to a method of manufacturing a semiconductor device and an apparatus for manufacturing the semiconductor device.

### BACKGROUND

According to the related art, there are semiconductor devices in which a metal wiring is installed inside an inter-layer insulation film. For example, the metal wiring is formed by forming a metal film such as a Cu film on the surface of the inter-layer insulation film in which an concave portion such as a wiring groove is formed, and then removing the metal film of an unnecessary portion formed on the surface of the inter-layer insulation film other than the concave portion by CMP (Chemical Mechanical Polishing).

In the CMP, the surface of a metal film is chemically and mechanically polished by performing polishing while supplying the surface of a metal film to be polished with a slurry including a chemical used to chemically polish the surface of the metal film and abrasive grains used to mechanically polish the surface of the metal film. In the CMP, however, when the film thickness of a metal film to be polished increases, there is a problem that a polishing time increases.

### BRIEF DESCRIPTION OF THE DRAWINGS

FIGS. 1 to 3 are schematic diagrams illustrating an apparatus for manufacturing a semiconductor device according to an embodiment; and

FIGS. 4A to 4D are schematic sectional views illustrating processes of manufacturing the semiconductor device in the manufacturing apparatus according to the embodiment.

### DETAILED DESCRIPTION

According to an embodiment, a method of manufacturing a semiconductor device is provided. The method of manufacturing the semiconductor device includes a process of forming a metal film on the surface of the insulation film with which a concave portion is filled and a first polishing process of polishing the surface of the metal film while supplying an oxidation agent containing no abrasive grains.

Hereinafter, a method of manufacturing a semiconductor device and an apparatus for manufacturing the semiconductor device will be described in detail with reference to the appended drawings according to an embodiment. The invention is not limited to the embodiment.

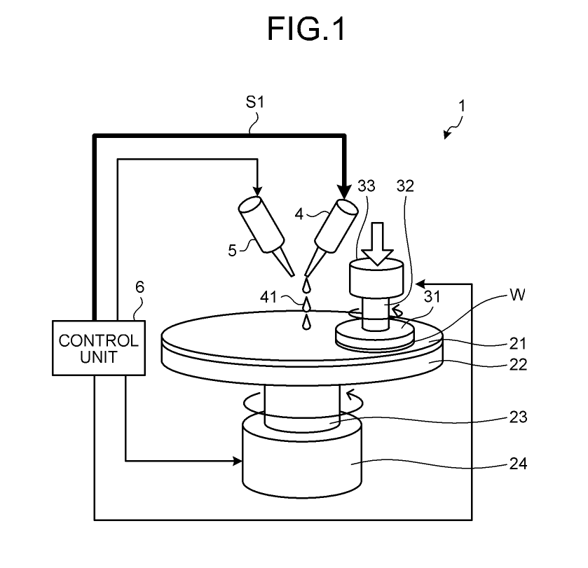

FIGS. 1 to 3 are schematic diagrams illustrating an apparatus (hereinafter, simply referred to as a “manufacturing apparatus 1”) for manufacturing a semiconductor device according to the embodiment. The manufacturing apparatus 1 illustrated in FIG. 1 is, for example, an apparatus that performs CMP (Chemical Mechanical Polishing) on a semiconductor wafer (hereinafter, referred to as a “wafer W”).

As illustrated in FIG. 1, for example, the manufacturing apparatus 1 includes a polishing plate 22 in which a polishing cloth 21 made of a resin such as a foam polyurethane is adhered on an upper surface and a table driving unit 24 that rotates a rotational shaft 23 connected to the bottom surface of the polishing plate 22. Further, the polishing cloth 21 is not limited to a foamable resin, but may be made of a non-foam resin or a non-woven cloth.

The manufacturing apparatus 1 further includes a polishing head 31 that adsorbs and holds the opposite surface to a polished surface of a wafer W to be polished and a head driving unit 33 that rotates a rotational shaft 32 connected to the upper surface of the polishing head 31.

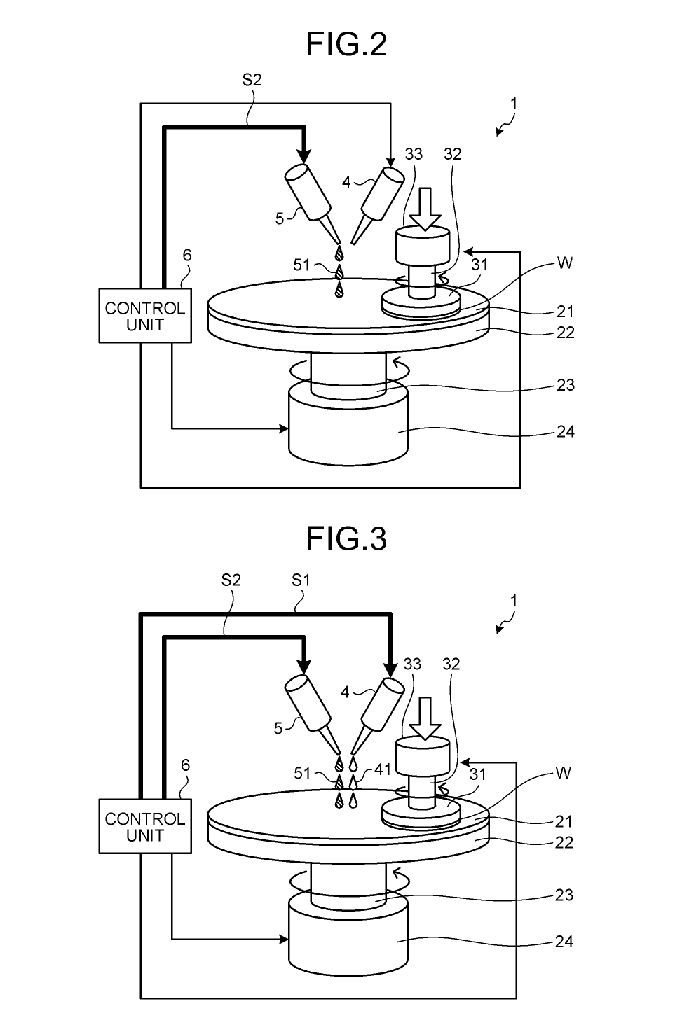

The manufacturing apparatus 1 further includes an oxidation agent supplying unit 4 that supplies an oxidation agent 41 containing no abrasive grains to the polishing cloth 21 and a polishing agent supplying unit 5 that supplies a polishing agent 51 (see FIG. 2) containing abrasive grains excluding the oxidation agent 41 to the polishing cloth 21. The manufacturing apparatus 1 further includes a control unit 6 that controls operations of the plate driving unit 24, the head driving unit 33, and the oxidation agent supplying unit 4, and the polishing agent supplying unit 5.

In the manufacturing apparatus 1, the polishing cloth 21, the polishing plate 22, the rotational shaft 23, the plate driving unit 24, the polishing head 31, the rotational shaft 32, and the head driving unit 33 cooperate to function as a polishing unit that polishes a polishing target.

In general, the manufacturing apparatus 1 simultaneously rotates the polishing plate 22 and the polishing head 31 in a state in which the polished surface of the wafer W adsorbed and held by the polishing head 31 is pressed against the upper surface of the polishing cloth 21, while supplying both of the oxidation agent 41 and the polishing agent 51 to the polishing cloth 21. That is, the manufacturing apparatus 1 generally performs CMP by simultaneously performing chemical polishing using the oxidation agent 41 supplied to the wafer W via the polishing cloth 21 and mechanical polishing using the polishing agent 51.

Here, in the general polishing agent 51, a polishing inhibitor is added together with abrasive grains to suppress extremely excessive polishing. Therefore, in a conventional general CMP method of polishing the wafer W while supplying both of the oxidation agent 41 and the polishing agent 51 to the wafer W, there is no problem when the film thickness of a portion to be polished is thin. However, when the film thickness of a portion to be polished increases, there is a problem that a polishing time increases. Further, as the polishing time increases, there is a problem that the use amount of the polishing agent 51 or the oxidation agent 41 also increase.

The polishing time can be shortened to some extent by increasing a pressing force (see a white arrow illustrated in FIG. 1) applied to the wafer W or increasing the rotation speed of the wafer W. However, since uneven selectivity of polishing is disordered due to the property of the polishing agent 51, it is difficult to maintain flatness of the polished surface.

Accordingly, when the film thickness of a portion to be polished is relatively thick, as illustrated in FIG. 1, the control unit 6 of the manufacturing apparatus 1 first outputs a supply instruction S1 to supply the oxidation agent 41 to the oxidation agent supplying unit 4 and perform a first polishing process by rotating the polishing plate 22 and the polishing head 31.

Thus, since the manufacturing apparatus 1 can polish the portion to be polished in a state in which a polishing inhibition force is excluded by the polishing inhibitor contained in the polishing agent 51, it is possible to shorten the polishing time of the portion to be polished and also reduce the use amount of the polishing agent 51.

The control unit 6 stops the polishing (the first polishing process) performed by supplying the oxidation agent 41, before the polishing amount of the portion to be polished reaches a desired polishing amount. At this time point, most of the portion to be polished is polished. Further, a time in which the portion to be polished is polished while supplying the oxidation agent 41 without supply of the polishing agent 51 is determined by an experiment carried out in advance.

Thereafter, in the manufacturing apparatus 1, to cause the polishing amount of the portion to be polished to reach the desired polishing amount and improve flatness of the polished surface, it is necessary to polish the wafer W while supplying the polishing agent 51 and the oxidation agent 41 to the polishing cloth 21. Further, in the manufacturing apparatus 1, it is necessary to perform dressing of removing the shavings or the reacted oxidation agent of the wafer W from the polishing cloth 21 before the polishing agent 51 or the oxidation agent 41 is newly supplied to the polishing cloth 21.

Here, when the dressing of the polishing cloth 21 is performed, the polished surface is oxidized by the oxidation agent 41 remaining on the polished surface of the wafer W during a dressing period, and thus an oxidized film is formed. The oxidation film is an oxidation film unnecessary in a semiconductor device and disturbs chemical polishing using the oxidation agent 41 when polishing is subsequently performed while supplying the polishing agent 51 and the oxidation agent 41 to the polishing cloth 21.

Accordingly, after the dressing ends, as illustrated in FIG. 2, the control unit 6 of the manufacturing apparatus 1 performs a second polishing process by outputting a supply instruction S2 to supply the polishing agent 51 to the polishing agent supplying unit 5 and rotating the polishing plate 22 and the polishing head 31. Thus, it is possible to remove an unnecessary oxidization film formed in the polished surface of the wafer W by mechanical polishing.

After the mechanical polishing (the second polishing process) ends, dressing of the polishing cloth 21 is performed again. However, in the mechanical polishing, it is difficult to form an oxidation film on the polished surface of the wafer W, since the oxidation agent 41 is not used.

Thereafter, as illustrated in FIG. 3, the control unit 6 outputs the supply instruction S1 to supply the oxidation agent 41 to the oxidation agent supplying unit 4 and the supply instruction S2 to supply the polishing agent 51 to the polishing agent supplying unit 5, and then performs a third polishing process by rotating the polishing plate 22 and the polishing head 31. Thus, by causing the polishing amount of the portion to be polished in the wafer W to reach a desired polishing amount, it is possible to improve the flatness of the polished surface.

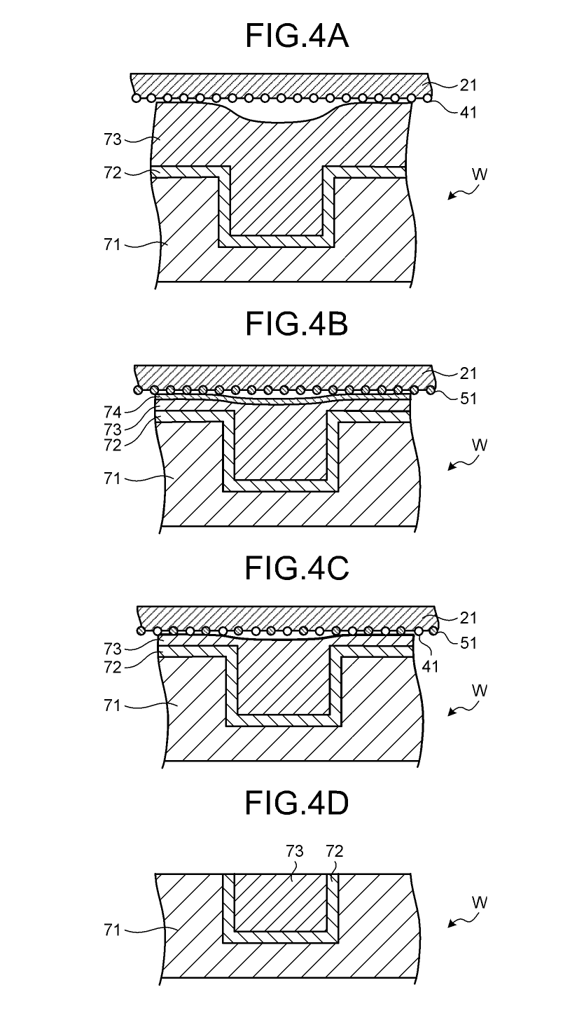

Next, an example of the polishing of a polishing target to be polished by the manufacturing apparatus 1 will be described with reference to FIGS. 4A to 4D. FIGS. 4A to 4D are schematic sectional views illustrating processes of manufacturing a semiconductor device in the manufacturing apparatus 1 according to the embodiment. In FIGS. 4A to 4D, the top and bottom of the wafer W are turned upside down from the state illustrated in FIGS. 1 to 3, that is, the adsorbed surface of the wafer W by the polishing head 31 faces downward and the polished surface by the polishing cloth 21 faces upward.

Here, a process of filling a Cu (copper) film 73 used as an inductor for a short-range communication inside an inter-layer insulation film 71 and removing the Cu film 73 of an unnecessary portion by polishing will be described as an example. The Cu film 73 used as the inductor is formed to be thicker by about three times than the thickness of the wafer W in its thickness direction, compared to other general metal wirings filled inside the inter-layer insulation film 71.

As illustrated in FIG. 4A, the Cu film 73 used as the inductor is filled inside the inter-layer insulation film 71 such as an oxidation silicon, an concave portion in which the Cu film 73 is filled is first formed at a predetermined position of the inter-layer insulation film 71 using a photolithographic technology and a dry etching technology.

Next, a TaN (tantalum nitride) film 72 is formed as a barrier metal on the surface of the inter-layer insulation film 71 including the concave portion by, for example, CVD (Chemical Vapor Deposition). Thereafter, for example, a Cu film 73 with a film thickness of about 6 μm is formed on the surface of the TaN film 72 including the concave portion by, for example, an electric field plating method. Thus, the Cu film 73 is filled inside the concave portion and the Cu film 73 with the film thickness of about 6 μm is formed on the surface of the TaN film 72 other than the concave portion.

The manufacturing apparatus 1 removes the TaN film 72 and the Cu film 73 having the film thickness of about 6 μm from the surface of the inter-layer insulation film 71 other than the concave portion by the polishing. Specifically, as illustrated in FIG. 4A, the manufacturing apparatus 1 performs the first polishing process of polishing the surface of the Cu film 73 while supplying the oxidation agent 41 containing no abrasive grains to the surface of the Cu film 73 through the polishing cloth 21. Here, since the polishing target is the Cu film 73, for example, APS (Ammonium Persulfate) is used as the oxidation agent 41.

At this time, the manufacturing apparatus 1 performs the first polishing process using the oxidation agent 41 while applying, for example, a pressing force of about 300 hPa to the wafer W in a direction (see the white arrow illustrated in FIG. 1) oriented from the polishing head 31 to the polishing cloth 21.

Here, if no pressing force is applied to the wafer W and the oxidation agent 41 is merely supplied to the surface of the Cu film 73, the same reaction as wet etching is caused on the surface of the Cu film 73. Therefore, the entire surface of the Cu film 73 including the concave portion is scraped away at an equal speed.

In this state, when the Cu film 73 in the concave portion is etched up to a desired depth, the unnecessary Cu film 73 considerably remain on the inter-layer insulation film 71 other than the concave portion. Further, in this case, the flatness of the surface of the Cu film 73 is not improved, since the film thickness thereof is thinned with the shape of the concave portion remaining.

On the other hand, the manufacturing apparatus 1 polishes the surface of the Cu film 73 while tightly pressing the Cu film 73 against the polishing cloth 21 by a predetermined pressing force and supplying the oxidation agent 41. Thus, the manufacturing apparatus 1 polishes a portion of the surface of the Cu film 73 which comes into contact with the polishing cloth 21, that is, the portion other than the concave portion, in preference to the concave portion. Accordingly, the manufacturing apparatus 1 can polish the Cu film 73 in a short time, while improving the flatness of the Cu film 73, compared to a case in which the polishing agent 51 is combined.

Thereafter, the manufacturing apparatus 1 ends the polishing of supplying the oxidation agent 41, when the thickness of the Cu film 73 remaining on the TaN film 72 other than concave portion is, for example, about 2 μm. Here, the manufacturing apparatus 1 continues the polishing of supplying the oxidation agent 41 for, for example, 30 seconds to 60 seconds, and ends the polishing.

Next, the manufacturing apparatus 1 performing the above-described dressing of the polishing cloth 21. As illustrated in FIG. 4B, during the dressing, a copper oxide film 74 which is an unnecessary oxidation film described above, may be formed on the surface of the Cu film 73, in some cases.

Accordingly, as illustrated in FIG. 4B, the manufacturing apparatus 1 performs the second polishing to polish and remove the copper oxide film 74 on the surface of the Cu film 73 while supplying the polishing agent 51 containing the abrasive grains excluding the oxidation agent 41 to the surface of the Cu film 73 through the polishing cloth 21. Here, the manufacturing apparatus 1 continues the second polishing process of supplying the polishing agent 51 for, for example, about 30 seconds to remove the copper oxide film 74.

The polishing agent 51 contains, as the abrasive grains, particles such as silicon oxide, aluminum oxide, alumina, cerium oxide, manganese oxide, and diamond with a diameter of several 10 nm to several 100 nm. Thereafter, the manufacturing apparatus 1 performs the above-described dressing of the polishing cloth 21.

Next, as illustrated in FIG. 4C, the manufacturing apparatus 1 performs the third polishing process of polishing the surface of the Cu film 73, while supplying both of the oxidation agent 41 and the polishing agent 51 to the surface of the Cu film 73 through the polishing cloth 21. Further, as illustrated in FIG. 4C, the manufacturing apparatus 1 continues the polishing to remove the TaN film 72 other than the concave portion by polishing and form the Cu film 73 used as the inductor filled in the inter-layer insulation film 71. Here, the manufacturing apparatus 1 continues the polishing while supplying both of the oxidation agent 41 and the polishing agent 51 for, for example, 5 minutes and ends the polishing.

As described above, the method of manufacturing the semiconductor device according to the embodiment includes a process of forming a metal film on the surface of an insulation film with which a concave portion is filled and a first polishing process of polishing the surface of the metal film while supplying an oxidation agent containing no abrasive grains.

Thus, according to the method of manufacturing the semiconductor device according to the embodiment, it is possible to shorten the polishing time of the metal film, compared to a case in which the surface of the metal film is polished while supplying both of the oxidation agent and the polishing agent to the surface of the metal film. Further, according to the method of manufacturing the semiconductor device according to the embodiment, it is possible to reduce the use amounts of the polishing agent and the oxidation agent used to polish the metal film, compared to the case in which the surface of the metal film is polished while supplying both of the oxidation agent and the polishing agent to the surface of the metal film.

The method of manufacturing the semiconductor device according to the embodiment includes the second polishing process of polishing the surface of the metal film while supplying the polishing agent excluding the oxidation agent to the surface of the metal film oxidized by the oxidation agent, after the first polishing process.

Thus, according to the method of manufacturing the semiconductor device according to the embodiment, it is possible to remove the unnecessary oxidation film disturbing the chemical polishing by the oxidation agent by the mechanical polishing by the polishing agent, when the polishing is subsequently performed while supplying the polishing agent and the oxidation agent to the metal film.

The method of manufacturing the semiconductor device according to the embodiment includes the third polishing process of polishing the surface of the metal film, while supplying the oxidation agent and the polishing agent to the surface to the metal film polished by the polishing agent, after the second polishing process is performed. Thus, according to the method of manufacturing the semiconductor device according to the embodiment, it is possible to improve the flatness of the final polished surface.

When the metal film polished by the method of manufacturing the semiconductor device according to the embodiment contains copper as a main component, it is possible to shorten a formation time of, for example, an inductor, a conductor, a capacitor, a through electrode (Cu plug), and a Cu wiring formed by filling the Cu film in the inter-layer insulation film.

In the above-described embodiment, the case in which the polishing target is the Cu film has been described. However, the polishing target polished by the method of manufacturing the semiconductor device and the manufacturing apparatus according to the embodiment is not limited to the Cu film. That is, the polishing target may be any metal film, such as tungsten, aluminum, or ruthenium, which can be polished by acid.

When the polishing target is tungsten, for example, H₂O₂ (hydrogen peroxide), Fe(NO₃)₃ (iron nitrate), or APS is used as the oxidation agent. When the polishing target is aluminum, for example, H₂O₂ or APS is used as the oxidation agent. When the polishing target is ruthenium, H₂O₂ is used as the oxidation agent.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
forming a metal film on a surface of the insulation film with which a concave portion is filled; and
polishing the surface of the metal film while supplying an oxidation agent containing no abrasive grains.

2. The method according to claim 1, further comprising:
polishing the surface of the metal film while supplying the oxidation agent containing no abrasive grains, and then polishing the surface of the metal film while supplying a polishing agent excluding the oxidation agent to the surface of the metal film oxidized by the oxidation agent.

3. The method according to claim 2, further comprising:
polishing the surface of the metal film while supplying the polishing agent excluding the oxidation agent, and then polishing the surface of the metal film while supplying the oxidation agent and the polishing agent to the surface of the metal film polished by the polishing agent.

4. The method according to claim 1, wherein the metal film contains copper as a main component.

5. The method according to claim 1, further comprising:
stopping the polishing of supplying the oxidation agent containing no abrasive grains, before a polishing amount of the metal film reaches a desired polishing amount.

6. The method according to claim 2, further comprising:
performing dressing of removing shavings and the reacted oxidation agent from a polishing cloth used to polish the metal film after the surface of the metal film is polished while supplying the oxidation agent containing no abrasive grains and before the surface of the metal film is polished while supplying the polishing agent excluding the oxidation agent.

7. The method according to claim 2, further comprising:
stopping the polishing of supplying the polishing agent excluding the oxidation agent, before a polishing amount of the metal film reaches a desired polishing amount.

8. The method according to claim 3, further comprising:
performing dressing of removing shavings from a polishing cloth used to polish the metal film after the surface of the metal film is polished while supplying the polishing agent excluding the oxidation agent and before the surface of the metal film is polished while supplying the oxidation agent and the polishing agent.

9. The method according to claim 3, further comprising:
stopping the polishing of supplying the oxidation agent and the polishing agent, when a polishing amount of the metal film reaches a desired polishing amount.

10. The method according to claim 1, further comprising:
forming the concave portion with a size, which is able to be filled with the metal film used as an inductor in the insulation film.

11. The method according to claim 1, further comprising:
applying a predetermined pressing force to the metal film by a polishing head performing the polishing, when the polishing is performed while supplying the oxidation agent containing no abrasive grains.

12. The method according to claim 4, wherein the oxidation agent includes ammonium persulfate.

13. The method according to claim 1, wherein the abrasive grains include at least one of particles of silicon oxide, aluminum oxide, alumina, cerium oxide, manganese oxide, and diamond with a diameter of several 10 nm to several 100 nm.

14. The method according to claim 1, further comprising:
forming the concave portion with a size, which is able to be filled with the metal film used as an capacitor, a through electrode, or a wiring in the insulation film.

15. The method according to claim 1,
wherein the metal film is tungsten, and
the oxidation agent includes at least one of hydrogen peroxide, iron nitrate, and ammonium persulfate.

16. The method according to claim 1,
wherein the metal film is aluminum, and
the oxidation agent includes at least one of hydrogen peroxide and ammonium persulfate.

17. An apparatus for manufacturing a semiconductor device, comprising:
an oxidation agent supplying unit that supplies an oxidation agent containing no abrasive grains to a polishing target;
a polishing agent supplying unit that supplies a polishing agent excluding the oxidation agent to the polishing target;
a polishing unit that polishes the polishing target; and
a control unit that
causes the polishing unit to polish a surface of a metal film formed on a surface of an insulation film with which a concave portion is filled, while causing the oxidation agent supplying unit to supply the oxidation agent to the surface of the metal film,
causes the polishing unit to polish the surface of the metal film, while causing the polishing agent supplying unit to supply the polishing agent to the surface of the metal film oxidized by the oxidation agent, and then
causes the polishing unit to polish the surface of the metal film, while causing the oxidation agent supplying unit and the polishing agent supplying unit to supply the oxidation agent and the polishing agent to the surface of the metal film polished by the polishing agent.
